(19) United States
(12) Patent Application Publication
(10) Pub. No.: US 2025/0143145 A1
(43) Pub. Date: May 1, 2025

(54) DISPLAY DEVICE

(71) Applicant: LG Display Co., Ltd., Seoul (KR)

(72) Inventor: YeounJei JUNG, Paju-si (KR)

(73) Assignee: LG Display Co., Ltd., Seoul (KR)

(21) Appl. No.: 18/765,071

(22) Filed: Jul. 5, 2024

(30) Foreign Application Priority Data
Oct. 30, 2023 (KR) 10-2023-0146792

(51) Int. Cl. H10K 59/80

(52) U.S. Cl. CPC H10K 59/873

(57) ABSTRACT

A display device in one example includes a first passivation layer and a second passivation layer configured to cover the first passivation layer. The first passivation layer includes a first insulating layer and a second insulating layer disposed on a portion of the first insulating layer. The second passivation layer provides an advantage of preventing oxygen or moisture from penetrating into an encapsulation layer.

### CROSS-REFERENCE TO RELATED APPLICATION

This application claims priority to Republic of Korea Patent Application No. 10-2023-0146792, filed on Oct. 30, 2023 in the Korean Intellectual Property Office, the entire contents of which is hereby expressly incorporated by reference into the present application.

### BACKGROUND

### Field

The present disclosure relates to electronic devices with displays, and more specifically, for example, without limitation, to display devices capable of preventing moisture or oxygen from penetrating into an encapsulation layer.

### Discussion of the Related Art

As the information-oriented society has been developed, various needs for display devices for displaying images have increased. Recently, various types of display devices, such as liquid crystal display (LCD) devices, organic light emitting diode (OLED) display devices, and the like have been developed and widely used.

A display panel included in a display device can include a display area and a non-display area.

The display area of the display panel can include a through hole, and an optical device can be disposed under the through hole.

The description provided in the discussion of the related art section should not be assumed to be prior art merely because it is mentioned in or associated with that section. The discussion of the related art section can include information that describes one or more aspects of the subject technology, and the description in this section does not limit the invention.

### SUMMARY OF THE DISCLOSURE

In a case where such a through hole is formed in a display panel to install an optical device in a display device, the display device can suffer from the penetration of moisture into the display panel.

To address this issue, one or more aspects of the present disclosure can provide a display device capable of preventing moisture or oxygen from penetrating into an encapsulation layer.

One or more aspects of the present disclosure can provide a display device including an encapsulation layer capable of preventing penetration of moisture during the process of forming a through hole.

One or more aspects of the present disclosure can provide a display device including a second encapsulation layer that is located on a first encapsulation layer, which is an inorganic layer, has high spreadability, and is capable of preventing moisture or oxygen from penetrating into the first encapsulation layer.

One or more aspects of the present disclosure can provide a display device capable of preventing moisture or oxygen from penetrating into an encapsulation layer and thereby being driven at low power.

According to one or more example embodiments of the present disclosure, a display device can be provided that includes a substrate including a through hole and a surrounding area surrounding the through hole, a first passivation layer disposed on the substrate and including a first insulating layer and a second insulating layer disposed on a portion of the first insulating layer, and a second passivation layer configured to cover the first passivation layer.

In one or more aspects, the substrate can comprise a first substrate, and a second substrate with an interlayer insulating layer interposed therebetween.

In one or more aspects, the second passivation layer can be configured to cover a side surface of the second insulating layer and a portion of a top surface of the first insulating layer.

In one or more aspects, the second passivation layer can be disposed in a stepped pattern.

In one or more aspects, the first passivation layer can be disposed in a stepped pattern.

In one or more aspects, the first passivation layer can be disposed to be spaced apart from the through hole, and the second passivation layer can be disposed adjacent to the through hole.

In one or more aspects, the second insulating layer can include a groove area where a plurality of grooves are disposed.

According to one or more aspects of the present disclosure, a display device can be provided that is capable of preventing moisture or oxygen from penetrating into an encapsulation layer.

According to one or more aspects of the present disclosure, a display device can be provided that includes an encapsulation layer capable of preventing penetration of moisture during the process of forming a through hole.

According to one or more aspects of the present disclosure, a display device can be provided that includes a second encapsulation layer that is located on a first encapsulation layer, which is an inorganic layer, has high spreadability, and is capable of preventing moisture or oxygen from penetrating into the first encapsulation layer.

According to one or more aspects of the present disclosure, a display device can be provided that is capable of preventing moisture or oxygen from penetrating into an encapsulation layer and thereby being driven at low power.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIGS. 1A, 1B and 1C are plan views illustrating an example display device according to aspects of the present disclosure;

FIG. 2 illustrates an example system configuration of the display device according to aspects of the present disclosure;

FIG. 3 is an example cross-sectional view of a display area in the display device according to aspects of the present disclosure;

FIG. 4 is an enlarged plan view illustrating an example optical area structure of the display panel in the display device according to aspects of the present disclosure;

FIG. 5 is a cross-sectional view taken along line I-I′ in the optical area of FIG. 4;

FIGS. 6 and 7 are cross-sectional views taken along line I-I′ in the optical area of FIG. 4;

FIGS. 8 to 11 are cross-sectional views illustrating a boundary area between a contact hole and a surrounding area in FIG. 4; and

FIGS. 12 and 13 are plan views illustrating a boundary area between the contact hole and the surrounding area in FIG. 4.

Throughout the drawings and the detailed description, unless otherwise described, the same drawing reference numerals should be understood to refer to the same elements, features, and structures. The sizes, lengths, and thicknesses of layers, regions and elements, and depiction thereof can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. In the following description, the structures, embodiments, implementations, methods and operations described herein are not limited to the specific example or examples set forth herein and can be changed as is known in the art, unless otherwise specified. Like reference numerals designate like elements throughout, unless otherwise specified. Names of the respective elements used in the following explanations are selected only for convenience of writing the disclosure and can thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents. In the following description, where the detailed description of the relevant known function or configuration can unnecessarily obscure aspects of the present disclosure, a detailed description of such known function or configuration can be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements can be added unless the term, such as “only,” is used. An element described in the singular form is intended to include a plurality of elements, and vice versa, unless the context clearly indicates otherwise.

In describing a temporal relationship, for example, when the temporal order is described as “after,” “subsequent,” “next,” and “before,” a case which is not continuous can be included, unless “just”, “immediate(ly)” or “direct(ly)” is used.

Although the terms “first,” “second,” A, B, (a), (b), and the like can be used herein to describe various elements, these elements should not be interpreted to be limited by these terms as they are not used to define a particular order, sequence or precedence. These terms are used only to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” can include all combinations of two or more elements selected from the first, second and third elements as well as each individual element of the first, second and third elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, with reference to the accompanying drawings, various example embodiments of the present disclosure will be described in detail. All the components of each display device or apparatus according to all embodiments of the present disclosure are operatively coupled and configured.

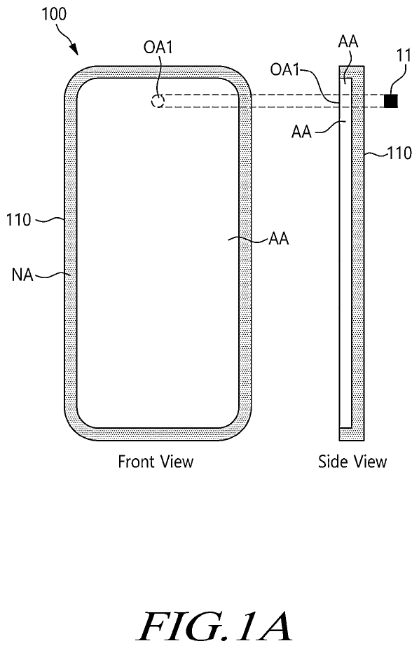

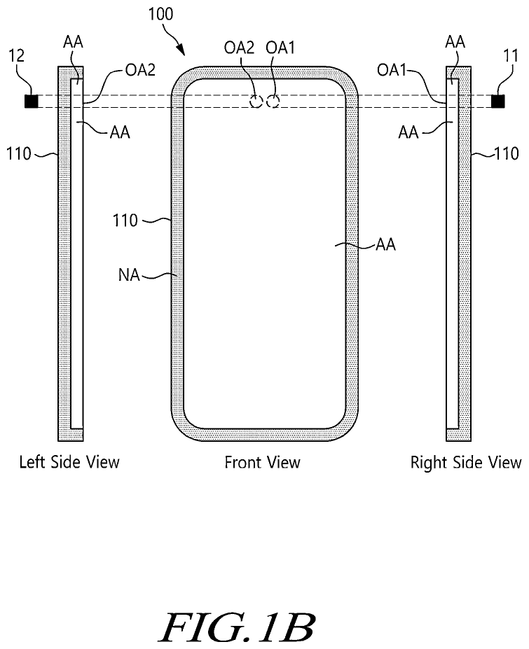

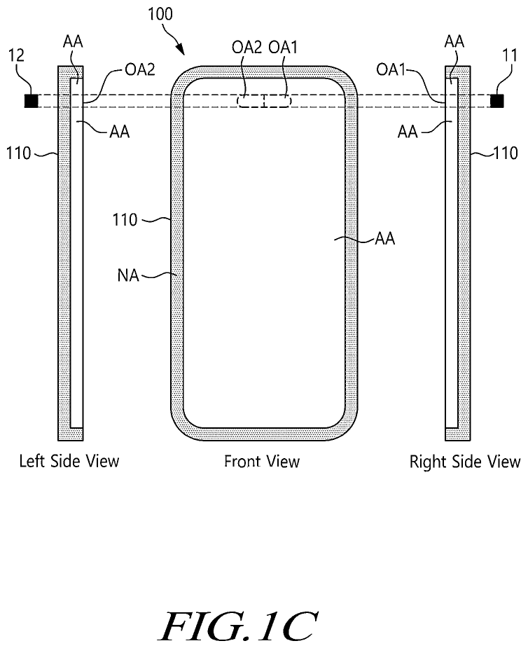

FIGS. 1A, 1B and 1C are plan views illustrating an example display device 100 according to aspects of the present disclosure.

Referring to FIGS. 1A, 1B, and 1C, in one or more example embodiments, a display device 100 can include a display panel 110 for displaying an image, one or more optical electronic devices (11 and/or 12), and the like. Herein, an optical electronic device can be referred to as a light detector, a light receiver, or a light sensing device. An optical electronic device can include one or more of a camera, a camera lens, a sensor, a sensor for detecting images, or the like.

The display panel 110 can include a display area (or active area) AA allowing an image to be displayed and a non-display area (or non-active area) NA in which an image is not displayed.

A plurality of subpixels can be disposed in the display area AA, and several types of signal lines for driving the plurality of subpixels can be disposed therein, without being limited thereto.

The non-display area NA can refer to an area outside of the display area AA. Several types of signal lines can be disposed in the non-display area NA, and several types of driving circuits can be connected thereto. At least a portion of the non-display area NA can be bent to be invisible from the front surface of the display device 100 or can be covered by a case or housing of the display device 100. The non-display area NA can be also referred to as an edge area or a bezel area.

In one or more aspects, in the display device 100, one or more optical electronic devices (11 and/or 12) can be prepared independently of, and installed in, the display panel 110, and be located under, or in a lower portion of, the display panel 110 (an opposite side of a viewing surface thereof), without being limited thereto. Alternatively, one or more optical electronic devices (11 and/or 12) can be integrally formed with the display panel 110.

Light can enter the front surface (the viewing surface) of the display panel 110, pass through the display panel 110, reach one or more optical electronic devices (11 and/or 12) located under, or in the lower portion of, the display panel 110 (the opposite side of the viewing surface).

The one or more optical electronic devices (11 and/or 12) can be devices capable of receiving or detecting light passing through the display panel 110 and perform a predefined function based on the received light. For example, the one or more optical electronic devices (11 and/or 12) can include one or more of the following: an image capture device such as a camera (an image sensor), and/or the like; or a sensor such as a proximity sensor, an illuminance sensor, and/or the like.

In one or more aspects, the display panel 110 can include one or more optical areas (OA1 and/or OA2), without being limited thereto. As shown in the example of FIG. 1A, the display panel 110 can include the first optical area OA1. As shown in the example of FIG. 1B, the display panel 110 can include the first optical area OA1 and the second optical area OA2.

The one or more optical areas (OA1 and/or OA2) can be one or more areas overlapping with the one or more optical electronic devices (11 and/or 12). For example, the optical area OA1 is an area overlapping with the first optical electronic device 11, and the optical area OA2 is an area overlapping with the second optical electronic device 12.

As shown in the example of FIG. 1A, the display area AA can be located outside of the first optical area OA1. The display area AA can be configured to surround the first optical area OA1. For example, at least a portion of the first optical area OA1 can overlap with the first optical electronic device 11. FIG. 1A illustrates a front view and a side view of the example display device according to aspects of the present disclosure.

As shown in the example of FIG. 1B, the display area AA can be located outside of the first optical area OA1 and the second optical area OA2. The display area AA can be configured to surround the first optical area OA1 and the second optical area OA2. Referring to FIG. 1B, a portion of the display area AA can be present between the first optical area OA1 and the second optical area OA2. In this implementation, at least a portion of the first optical area OA1 can overlap with the first optical electronic device 11, and at least a portion of the second optical area OA2 can overlap with the second optical electronic device 12. FIG. 1B illustrates a front view, a left side view and a right side view of the example display device according to aspects of the present disclosure.

As shown in the example of FIG. 1C, the display area AA can be located outside of the first optical area OA1 and the second optical area OA2. The display area AA can be configured to surround the first optical area OA1 and the second optical area OA2. Referring to FIG. 1C, the display area AA may not be present between the first optical area OA1 and the second optical area OA2. For example, the first optical area OA1 and the second optical area OA2 can contact each other (e.g., directly contact each other), without being limited thereto. In this implementation, at least a portion of the first optical area OA1 can overlap with the first optical electronic device 11, and at least a portion of the second optical area OA2 can overlap with the second optical electronic device 12. FIG. 1C illustrates a front view, a left side view and a right side view of the example display device according to aspects of the present disclosure.

In one or more aspects, the one or more optical areas (OA1 and/or OA2) are needed to be configured with a light transmissive structure. For example, to enable light to be transmitted through the one or more optical electronic devices (11 and/or 12), the one or more optical areas (OA1 and/or OA2) can be needed to have a light transmission structure.

In one or more aspects, the one or more optical electronic devices (11 and/or 12) that need to receive light can be exposed in the front surface (viewing surface) of the display panel 110 or the display device 100, without being limited thereto.

It should be noted that even though the one or more optical electronic devices (11 and/or 12) are devices that need to receive light, the one or more optical electronic devices (11 and/or 12) can be located on the back of the display panel 110 (e.g., on an opposite side of the viewing surface thereof), and thereby, can receive light that has passed through the display panel 110.

In one example, the first optical electronic device 11 can be, for example, a camera, and the second optical electronic device 12 can be, for example, a sensor, without being limited thereto. The sensor can be a proximity sensor, an illuminance sensor, an infrared sensor, and/or the like. For example, the camera can be a camera lens, an image sensor, or a unit including at least one of the camera lens and the image sensor, and the sensor can be an infrared sensor capable of detecting infrared light.

In another example, the first optical electronic device 11 can be, for example, a sensor, and the second optical electronic device 12 can be, for example, a camera. For example, the camera can be a camera lens, an image sensor, or a unit including at least one of the camera lens and the image sensor, and the sensor can be an infrared sensor capable of detecting infrared light.

Hereinafter, for convenience of description, discussions are provided based on examples where the first optical electronic device 11 is a camera, and the second optical electronic device 12 is a sensor, without being limited thereto. It should be, however, understood that the scope of the present disclosure includes embodiments where the first optical electronic device 11 is the sensor, and the second optical electronic device 12 is the camera. The camera can be, for example, a camera lens, an image sensor, or a unit including at least one of the camera lens and the image sensor.

In an example where the first optical electronic device 11 is a camera, this camera can be located on the back of (e.g., under, or in a lower portion of) the display panel 110, and be a front camera capable of capturing objects or images in a front direction of the display panel 110. Accordingly, a user can capture an image or object through the first optical electronic device 11 such as a camera while looking at the viewing surface of the display panel 110.

In the examples of FIGS. 1A, 1B, and 1C, the first optical area OA1 can have various shapes, such as a circle, an ellipse, a quadrangle, a hexagon, an octagon or the like, without being limited thereto. In the examples of FIGS. 1B and 1C, the second optical area OA2 can have various shapes, such as a circle, an ellipse, a quadrangle, a hexagon, an octagon or the like, without being limited thereto. The first optical area OA1 and the second optical area OA2 can have the same or substantially or nearly the same shape, or have different shapes.

Referring to FIG. 1C, in the example where the first optical area OA1 and the second optical area OA2 contact each other (e.g., directly contact each other), the entire optical area including the first optical area OA1 and the second optical area OA2 can also have various shapes, such as a circle, an ellipse, a quadrangle, a hexagon, an octagon or the like, without being limited thereto.

Hereinafter, for convenience of descriptions related to shapes of the optical areas (OA1 and OA2), each of the first optical area OA1 and the second optical area OA2 is considered to have a circular shape. It should be, however, understood that the scope of the present disclosure includes examples where at least one of the first optical area OA1 and the second optical area OA2 have a shape other than a circular shape, such as an ellipse, a quadrangle, a hexagon, an octagon or the like, without being limited thereto.

In one or more aspects, when an implementation where the optical areas (OA1 and OA2) are surrounded by the display area AA is applied to the display device 100, this type of the display device 100 can be referred to as a display in which a hole-in-active area (HiAA) technology is applied.

In examples where this HiAA technology is applied to the display device 100, a notch for camera exposure may not be formed in the display panel 110. To apply this technology, the display device 100 can have a camera hole formed for camera exposure.

Since a notch does not need to be formed in the display panel 110, the display device 100 can have further advantages of reducing the size of the bezel area, and improving the degree of freedom in design because such limitations to the design are removed.

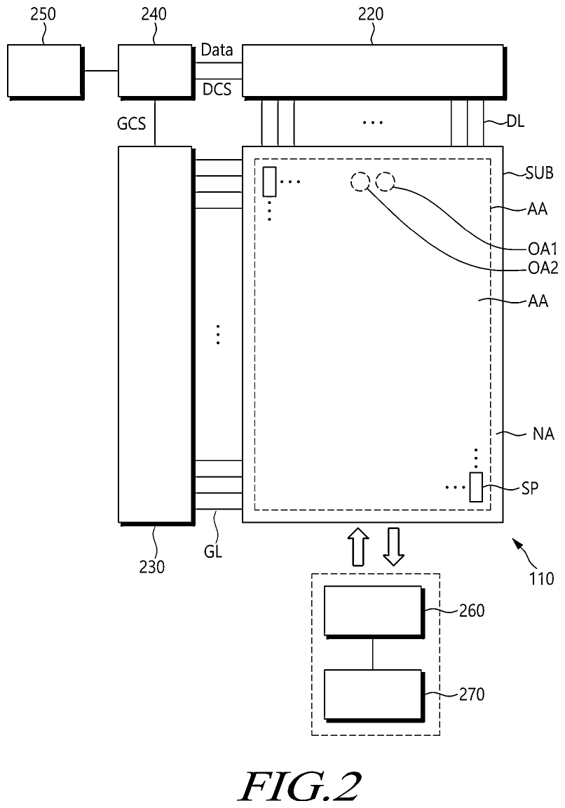

FIG. 2 illustrates an example system configuration of the display device 100 according to aspects of the present disclosure.

Referring to FIG. 2, the display device 100 can include the display panel 110 and a display driving circuit as components for displaying one or more images.

The display driving circuit can be a circuit for driving the display panel 110, and include, but is not limited to, a data driving circuit 220, a gate driving circuit 230, a display controller 240, and other circuit components.

The display panel 110 can include a display area AA allowing an image to be displayed and a non-display area NA in which an image is not displayed. The non-display area NA can be an area outside of the display area AA, and also be referred to as an edge area or a bezel area. All or a portion of the non-display area NA can be an area visible from the front surface of the display device 100, or an area that is bent and invisible from the front surface of the display device 100 or an area that is covered by a case or housing of the display device 100.

The display panel 110 can include a substrate SUB and a plurality of subpixels SP disposed on the substrate SUB, without being limited thereto. The display panel 110 can further include various types of signal lines to drive the plurality of subpixels SP. Further, the display panel 110 can include one or more optical areas (OA1 and/or OA2).

In one or more aspects, the display device 100 can be a liquid crystal display device (LCD), a plasma display device (PDP), a field emission display device (FED), or the like, or a self-emission display device in which light is emitted from the display panel 110 itself, such as an organic light-emitting display device (OLED), and a micro LED (Micro Light Emitting Diode) display device. In the example where the display device 100 is a self-emission display device, each of the plurality of subpixels SP can include a light emitting element.

For example, the display device 100 according to aspects of the present disclosure can be an organic light emitting display device in which light emitting elements ED are implemented using organic light emitting diodes (OLED). In another example, the display device 100 according to aspects of the present disclosure can be an inorganic light emitting display device in which light emitting elements are implemented using inorganic material-based light emitting diodes. In further another example, the display device 100 according to aspects of the present disclosure can be a quantum dot display device implemented with quantum dots, which are self-emission semiconductor crystals, as light emitting elements. However, the present disclosure is not limited thereto.

The structure of each of the plurality of subpixels SP can be differently configured or designed according to types of the display devices 100. In an example where the display device 100 is a self-emission display device including self-emission subpixels SP, each subpixel SP can include a self-emission light emitting element, one or more transistors, one or more capacitors, and the like.

The various types of signal lines can include, for example, a plurality of data lines DL for carrying data signals (which can be referred to as data voltages or image signals), a plurality of gate lines GL for carrying gate signals (which can be referred to as scan signals), and the like.

The plurality of data lines DL and the plurality of gate lines GL can intersect one another. Each of the plurality of data lines DL can be configured to extend in a first direction. Each of the plurality of gate lines GL can be configured to extend in a second direction different from the first direction.

For example, the first direction can be the column or vertical direction, and the second direction can be the row or horizontal direction, without being limited thereto. In another example, the first direction can be the row or horizontal direction, and the second direction can be the column or vertical direction.

The data driving circuit 220 can be a circuit for driving the plurality of data lines DL, and can supply data signals to the plurality of data lines DL. The gate driving circuit 230 can be a circuit for driving a plurality of gate lines GL, and can supply gate signals to the plurality of gate lines GL.

The display controller 240 can be a device for controlling the data driving circuit 220 and the gate driving circuit 230, and can control driving times for the plurality of data lines DL and driving times for the plurality of gate lines GL.

Specifically, the display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data based on the input image data to the data driving circuit 220.

The data driving circuit 220 can supply data signals to the plurality of data lines DL according to driving timing control of the display controller 240.

The data driving circuit 220 can receive digital image data Data from the display controller 240, convert the received image data Data into analog data signals, and output the resulting analog data signals to the plurality of data lines DL.

The gate driving circuit 230 can supply gate signals to the plurality of gate lines GL according to timing control of the display controller 240. The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more aspects, the data driving circuit 220 can be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique, without being limited thereto.

In one or more aspects, the gate driving circuit 230 can be connected to the display panel 110 by the tape-automated-bonding (TAB) technique, or connected to a conductive pad such as a bonding pad of the display panel 110 by the chip-on-glass (COG) technique or the chip-on-panel (COP) technique, or connected to the display panel 110 by the chip-on-film (COF) technique. In one or more aspects, the gate driving circuit 230 can be disposed in the non-display area NA of the display panel 110 by a gate-in-panel (GIP) technique, without being limited thereto. Alternatively, the gate driving circuit 230 can be disposed in the display area AA of the display panel 110. The gate driving circuit 230 can be disposed on the substrate SUB, or connected to the substrate SUB. In an example where the gate driving circuit 230 is implemented by the GIP technique, the gate driving circuit 230 can be disposed in the non-display area NA of the substrate SUB. The gate driving circuit 230 can be connected to the substrate SUB in an example where the gate driving circuit 230 is implemented by the chip-on-glass (COG) technique, the chip-on-film (COF) technique, or the like.

In one or more aspects, at least one of the data driving circuit 220 and the gate driving circuit 230 can be disposed in the display area AA of the display panel 110. For example, at least one of the data driving circuit 220 and the gate driving circuit 230 can be configured not to overlap with subpixels SP, or configured to overlap with one or more, or all, of the subpixels SP, or at least respective one or more portions of one or more subpixels, without being limited thereto.

The data driving circuit 220 can be located in, and/or electrically connected to, but not limited to, only one side or portion (e.g., an upper edge or a lower edge) of the display panel 110. In one or more aspects, the data driving circuit 220 can be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 230 can be located in, and/or electrically connected to, but not limited to, only one side or portion (e.g., a left edge or a right edge) of the display panel 110, without being limited thereto. Further, the gate driving circuit 230 can be located in, and/or electrically connected to, but not limited to, at least two of four sides or portions (e.g., an upper edge, a lower edge, the left edge, and the right edge) of the panel 110 according to driving schemes, panel design schemes, or the like. For example, the gate driving circuit 230 can be located in, and/or electrically connected to, but not limited to, two sides or portions (e.g., a left edge and a right edge) of the panel 110.

The display controller 240 can be implemented in a separate component from the data driving circuit 220, or incorporated in the data driving circuit 220 and thus implemented in an integrated circuit.

The display controller 240 can be a timing controller used in the typical display technology or a controller or a control device capable of performing other control functions in addition to the function of the typical timing controller. In one or more exemplary embodiments, the display controller 240 can be a controller or a control device different from the timing controller, or a circuitry or a component included in the controller or the control device. The display controller 240 can be implemented with various circuits or electronic components such as an integrated circuit (IC), a field programmable gate array (FPGA), an application specific integrated circuit (ASIC), a processor, and/or the like, without being limited thereto.

The display controller 240 can be mounted on a printed circuit board, a flexible printed circuit, and/or the like and be electrically connected to the gate driving circuit 230 and the data driving circuit 220 through the printed circuit board, flexible printed circuit, and/or the like.

The display controller 240 can transmit signals to, and receive signals from, the data driving circuit 220 via one or more predefined interfaces. For example, such interfaces can include, a low voltage differential signaling (LVDS) interface, an embedded clock point-point interface (EPI), a serial peripheral interface (SPI), and the like. Similarly, the display controller 240 can transmit signals to, and receive signals from, the gate driving circuit 230 via one or more predefined interfaces.

In one or more aspects, in order to further provide a touch sensing function, as well as an image display function, the display device 100 can further include at least one touch sensor, and a touch sensing circuit capable of detecting the occurrence of a touch event by a touch object such as a finger, a pen, or the like, or detecting a corresponding touch location (or touch coordinates), by sensing the touch sensor, and the like.

As one example, the touch sensing circuit can include, but is not limited to, a touch driving circuit 260 capable of generating and providing touch sensing data by driving and sensing the touch sensor, a touch controller 270 capable of detecting the occurrence of a touch event or detecting a touch location (or touch coordinates) using the touch sensing data, and one or more other components.

As one example, the touch sensor can include, but is not limited to, a plurality of touch electrodes. The touch sensor can further include a plurality of touch lines for electrically connecting the plurality of touch electrodes to the touch driving circuit 260.

The touch sensor can be implemented in the form of a touch panel outside of the display panel 110 or be integrated inside of the display panel 110. In the example where the touch sensor is implemented in the form of the touch panel outside of the display panel 110, such a touch sensor can be referred to as an add-on type. In the example where the add-on type of touch sensor is disposed in the display device 100, the touch panel and the display panel 110 can be separately manufactured and combined in an assembly process. The add-on type of touch panel can include a touch panel substrate and a plurality of touch electrodes on the touch panel substrate.

In the example where the touch sensor is integrated inside of the display panel 110, the touch sensor can be formed on the substrate SUB together with signal lines and electrodes related to display driving during the process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing. For example, the touch sensing circuit can perform touch sensing by a self-capacitance sensing technique or a mutual-capacitance sensing technique, without being limited thereto.

In the example where the touch sensing circuit performs touch sensing by the self-capacitance sensing technique, the touch sensing circuit can perform touch sensing based on capacitance between each touch electrode and a touch object (e.g., a finger, a pen, and the like).

According to the self-capacitance sensing technique, each of a plurality of touch electrodes can serve as both a driving touch electrode and a sensing touch electrode. The touch driving circuit 260 can drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes.

According to the mutual-capacitance sensing technique, a plurality of touch electrodes can be divided into driving touch electrodes and sensing touch electrodes. The touch driving circuit 260 can drive the driving touch electrodes and sense the sensing touch electrodes.

The touch driving circuit 260 and the touch controller 270 included in the touch sensing circuit can be implemented in separate devices or in a single device, without being limited thereto. Further, the touch driving circuit 260 and the data driving circuit 220 can be implemented in separate devices or in a single device, without being limited thereto.

The display device 100 can further include a power supply circuit for supplying various types of power to the display driving circuit and/or the touch sensing circuit.

In some aspects, the display device 100 can be a mobile terminal such as a notebook computer, a smart phone, a tablet, or the like, or a monitor, a television (TV), or the like, without being limited thereto. Such devices can be configured in various types, sizes, and shapes. The display device 100 according to aspects of the present disclosure are not limited thereto, and can include various types, sizes, and shapes of the display devices configured to display information or images.

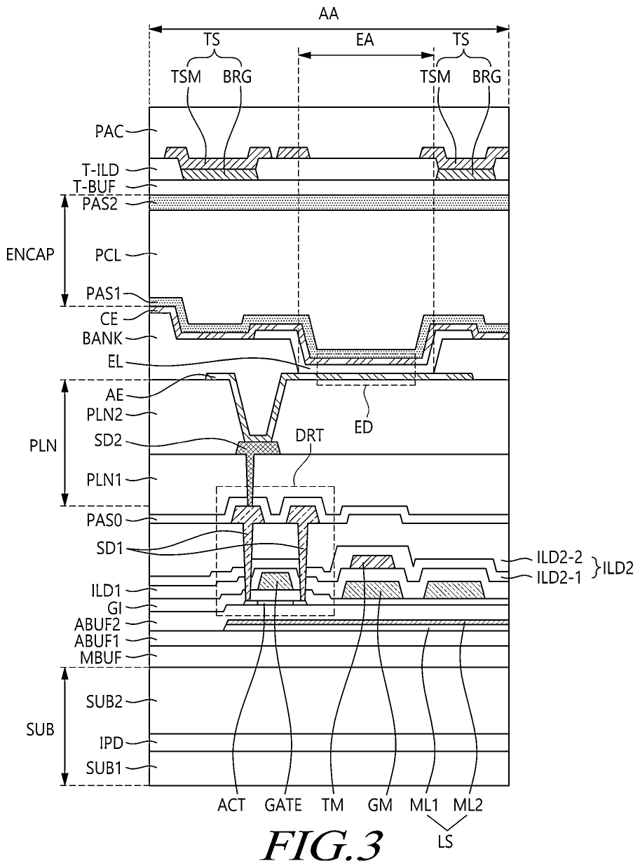

FIG. 3 is an example cross-sectional view of a portion of the display area AA of the display panel 110 according to aspects of the present disclosure.

Referring to FIG. 3, a substrate SUB can be disposed at the bottom of the display panel 110. For example, the substrate SUB can include a first substrate SUB1, an interlayer insulating layer IPD, and a second substrate SUB2. The interlayer insulating layer IPD can be interposed between the first substrate SUB1 and the second substrate SUB2. As shown in FIG. 3, the interlayer insulating layer IPD can be disposed on the first substrate SUB1, and the second substrate SUB2 can be disposed on the interlayer insulating layer IPD, without being limited thereto. As the substrate SUB includes the first substrate SUB1, the interlayer insulating layer IPD, and the second substrate SUB2, the substrate SUB can prevent or reduce the penetration of moisture or oxygen into the display panel 110. The first substrate SUB1 and the second substrate SUB2 can be, for example, polyimide (PI) substrates, without being limited thereto. The first substrate SUB1 can be referred to as a first primary PI substrate, and the second substrate SUB2 can be referred to as a second PI substrate.

Various types of patterns (ACT, SD1, GATE) for forming one or more transistors such as a driving transistor DRT, and the like, various types of insulating layers (MBUF, ABUF1, ABUF2, GI, ILD1, ILD2, PAS0), and various types of metal patterns (TM, GM, ML1, ML2) can be disposed on or over the substrate SUB.

A multi-buffer layer MBUF can be disposed on the second substrate SUB2, and a first active buffer layer ABUF1 can be disposed on the multi-buffer layer MBUF.

A first metal layer ML1 and a second metal layer ML2 can be disposed on the first active buffer layer ABUF1. For example, the first metal layer ML1 and the second metal layer ML2 can be light shield layers LS for shielding light.

A second active buffer layer ABUF2 can be disposed on the first metal layer ML1 and the second metal layer ML2. Specifically, the second active buffer layer ABUF2 can be disposed on the first active buffer layer ABUF1, the first metal layer ML1 and the second metal layer ML2. The active layer ACT of a driving transistor DRT can be disposed on the second active buffer layer ABUF2.

A gate insulating layer GI can be configured to cover the active layer ACT. Specifically, the gate insulating layer GI can be configured to cover the second active buffer layer ABUF2 and the active layer ACT.

The gate electrode GATE of the driving transistor DRT can be patterned and disposed on the gate insulating layer GI. In one aspect, together with the gate electrode GATE of the driving transistor DRT, a gate material layer GM can be disposed on the gate insulating layer GI, at a location different from a location where the driving transistor DRT is disposed.

A first interlayer insulating layer ILD1 can be configured to cover the gate electrode GATE and the gate material layer GM. Specifically, the first interlayer insulating layer ILD1 can be configured to cover the gate insulating layer GI, the gate electrode GATE and the gate material layer GM. A metal pattern TM can be patterned and disposed on the first interlayer insulating layer ILD1. The metal pattern TM can be located at a location different from the location where the driving transistor DRT is formed. A second interlayer insulating layer ILD2 can be configured to cover the metal pattern TM on the first interlayer insulating layer ILD1. Specifically, second interlayer insulating layer ILD2 can be configured to cover the metal pattern TM and the first interlayer insulating layer ILD1.

Two first source-drain electrode patterns SD1 can be patterned and disposed on the second interlayer insulating layer ILD2. One of the two first source-drain electrode patterns SD1 can be a source node of the driving transistor DRT, and the other thereof can be a drain node of the driving transistor DRT.

The two first source-drain electrode patterns SD1 can be electrically connected to first and second side portions of the active layer ACT, respectively, through contact holes formed in the second interlayer insulating layer ILD2, the first interlayer insulating layer ILD1, and the gate insulating layer GI.

The second interlayer insulating layer ILD2 can include a second-first interlayer insulating layer ILD2-1 and a second-second interlayer insulating layer ILD2-2. The second-first interlayer insulating layer ILD2-1 can be configured to cover the metal pattern TM. Specifically, the second-first interlayer insulating layer ILD2-1 can be configured to cover the metal pattern TM and the first interlayer insulating layer ILD1. The second-second interlayer insulating layer ILD2-2 can be located on the second-first interlayer insulating layer ILD2-1.

A portion of the active layer ACT overlapping the gate electrode GATE can serve as a channel region. One of the two first source-drain electrode patterns SD1 of the driving transistor DRT can be connected to the first side portion of the channel region of the active layer ACT, and the other of the two first source-drain electrode patterns SD1 can be connected to the second side portion of the channel region of the active layer ACT.

A passivation layer PAS0 can be configured to cover the two first source-drain electrode patterns SD1. Specifically, the passivation layer PAS0 can be configured to cover the two first source-drain electrode patterns SD1 and the second-second interlayer insulating layer ILD2-2. A planarization layer PLN can be disposed on the passivation layer PAS0. The planarization layer PLN can include a first planarization layer PLN1 and a second planarization layer PLN2.

The first planarization layer PLN1 can be disposed on the passivation layer PAS0. The second planarization layer PLN2 can be disposed on the first planarization layer PLN1.

A second source-drain electrode pattern SD2 can be patterned and disposed on the first planarization layer PLN1. The second source-drain electrode pattern SD2 can be connected to one of the two first source-drain electrode patterns SD1 through a contact hole formed in the first planarization layer PLN1.

The second planarization layer PLN2 can be configured to cover the second source-drain electrode pattern SD2. Specifically, the second planarization layer PLN2 can be disposed on the first planarization layer PLN1 and the second source-drain electrode pattern SD2. Thereafter, a portion of the second planarization layer PLN2 can be removed by etching. A light emitting element ED of a subpixel SP can be disposed on the second planarization layer PLN2.

According to an example stack structure of the light emitting element ED, an anode electrode AE can be disposed on the second planarization layer PLN2. The anode electrode AE can be electrically connected to the second source-drain electrode pattern SD2 through a contact hole formed in the second planarization layer PLN2. The anode electrode AE can have a multilayer structure including a transparent conductive film and an opaque conductive film having high reflective efficiency. The transparent conductive film can be made of a material having a relatively high work function value such as indium-tin-oxide (ITO) or indium-zinc-oxide (IZO), and the opaque conductive film can have a single-layer or multi-layer structure including Al, Ag, Cu, Pb, Mo, Ti or an alloy thereof.

A bank BANK can be configured to cover a portion of the anode electrode AE. Specifically, the bank BANK can be configured to cover a portion of the anode electrode AE and the second planarization layer PLN2. A portion of the bank BANK corresponding to the light emitting area EA of the subpixel SP can be opened. The bank BANK can include an insulating material. As an example, the bank BANK can include an organic insulating material such as acryl resin, epoxy resin, phenolic resin, polyamide resin, and/or polyimide resin, etc. Alternatively, the bank BANK can include an inorganic insulating material such as silicon nitride, aluminum nitride, zirconium nitride, titanium nitride, hafnium nitride, tantalum nitride, silicon oxide, aluminum oxide, or titanium oxide, etc. Further, the bank BANK can include a black dye in order to absorb light incident from the outside.

A portion of the anode electrode AE can be exposed through the opening (the opened portion) of the bank BANK. At least a portion of an emission layer EL can be located on at least one side surface of the bank BANK and in the opening (the opened portion) of the bank BANK. All or at least a portion of the emission layer EL can be located between adjacent banks.

In the opening of the bank BANK, the emission layer EL can contact the anode electrode AE. A cathode electrode CE can be disposed on the emission layer EL. Specifically, the cathode electrode CE can be disposed on the emission layer EL and a portion of the bank BANK.

The light emitting element ED can be formed by the anode electrode AE, the emission layer EL, and the cathode electrode CE. The emission layer EL can include an organic material layer. For example, the emission layer EL can include one or more of a hole injection layer (HIL), a hole transmitting layer (HTL), an electron transmitting layer (ETL) and an electron injection layer (EIL), but the present disclosure is not limited thereto.

An encapsulation layer ENCAP can be disposed on the stack of the light emitting element ED.

The encapsulation layer ENCAP can have a single-layer stack or a multi-layer stack. For example, as shown in FIG. 3, the encapsulation layer ENCAP can include a first encapsulation layer PAS1, a second encapsulation layer PCL, and a third encapsulation layer PAS2. The second encapsulation layer PCL can be interposed between the first encapsulation layer PAS1 and the third encapsulation layer PAS2.

For example, the first encapsulation layer PAS1 and the third encapsulation layer PAS2 can be inorganic layers, and the second encapsulation layer PCL can be an organic layer, without being limited thereto. For example, among the first encapsulation layer PAS1, the second encapsulation layer PCL, and the third encapsulation layer PAS2, the second encapsulation layer PCL can have a greatest thickness, without being limited thereto. In this example, the second encapsulation layer PCL can serve as a planarization layer. The first encapsulation layer PAS1, the second encapsulation layer PCL, and the third encapsulation layer PAS2 can be also referred to as a first inorganic encapsulation layer, an organic encapsulation layer, and a second inorganic encapsulation layer, respectively.

The first encapsulation layer PAS1 can be disposed on the cathode electrode CE and can be disposed closest to the stack of the light emitting element ED. The first encapsulation layer PAS1 can include an inorganic insulating material, which can be deposited at a low temperature. In one or more aspects, the first encapsulation layer PAS1 can include a plurality of insulating layers. For example, the first encapsulation layer PAS1 can include, but not limited to, silicon nitride (SiNx), silicon oxide (SiOx), silicon oxynitride (SiON), aluminum oxide (Al2O3), or the like. Since the first encapsulation layer PAS1 is deposited in a low temperature atmosphere, during the deposition process, the first encapsulation layer PAS1 can prevent the emission layer EL including an organic material vulnerable to a high temperature atmosphere from being damaged.

The second encapsulation layer PCL can have an area or size smaller than the first encapsulation layer PAS1 in a plan view. For example, the second encapsulation layer PCL can be configured to expose both ends or edges of the first encapsulation layer PAS1. The second encapsulation layer PCL can serve as a buffer for relieving stress between corresponding layers while the display device 100 is curved or bent, and also serve to enhance planarization performance. For example, the second encapsulation layer PCL can include an organic insulating material, such as acrylic resin, epoxy resin, polyimide, polyethylene, silicon oxycarbon (SiOC), or the like. The second encapsulation layer PCL can be formed, for example, by an inkjet technique.

The third encapsulation layer PAS2 can be disposed over the substrate SUB over which the second encapsulation layer PCL is disposed, and configured to cover the respective top surfaces and side surfaces of the second encapsulation layer PCL and the first encapsulation layer PAS1. The third encapsulation layer PAS2 can minimize or prevent external moisture or oxygen from penetrating into the first encapsulation layer PAS1 and the second encapsulation layer PCL. For example, the third encapsulation layer PAS2 can include an inorganic insulating material, such as silicon nitride (SiNx), silicon oxide (SiOx), silicon oxynitride (SiON), aluminum oxide (Al₂O₃), or the like.

Referring to FIG. 3, in an example where a touch sensor TS is embedded into the display panel 110, a touch sensor TS can be disposed on the encapsulation layer ENCAP. The structure of the touch sensor will be described in detail as follows.

A touch buffer layer T-BUF can be disposed on the encapsulation layer ENCAP. Specifically, the touch buffer layer T-BUF can be disposed on the third encapsulation layer PAS2. The touch sensor TS can be disposed on the touch buffer layer T-BUF.

The touch sensor TS can include touch sensor metals TSM and at least one bridge metal BRG, which are located in different layers. The touch sensor metals TSM can be disposed on the bridge metal BRG and a portion of the touch interlayer insulating layer T-ILD.

A touch interlayer insulating layer T-ILD can be disposed between the touch sensor metals TSM and the bridge metal BRG.

For example, the touch sensor metals TSM can include a first touch sensor metal TSM, a second touch sensor metal TSM, and a third touch sensor metal TSM, which are disposed adjacent to one another. In an example where the third touch sensor metal TSM is disposed between the first touch sensor metal TSM and the second touch sensor metal TSM, and the first touch sensor metal TSM and the second touch sensor metal TSM are required to be electrically connected to each other, the first touch sensor metal TSM and the second touch sensor metal TSM can be electrically connected to each other through the bridge metal BRG located in a different layer. The bridge metal BRG can be electrically insulated from the third touch sensor metal TSM by the touch interlayer insulating layer T-ILD.

While the touch sensor TS is disposed in the display panel 110, a chemical solution (e.g., a developer or etchant) used in the corresponding process or moisture from outside the display panel 110 can be generated or introduced. In this situation, by disposing the touch sensor TS on the touch buffer layer T-BUF, such a chemical solution or moisture can be prevented from penetrating into the emission layer EL including an organic material during the manufacturing process of the touch sensor TS. Accordingly, the touch buffer layer T-BUF can prevent damage to the emission layer EL, which is vulnerable to a chemical solution or moisture.

To prevent damage to the emission layer EL including an organic material, which is vulnerable to high temperatures, the touch buffer layer T-BUF can be formed at a low temperature less than or equal to a predetermined temperature (e.g. 100 degrees (° C.)) and be formed using an organic insulating material with a low permittivity of 1 to 3. For example, the touch buffer layer T-BUF can include an acrylic-based, epoxy-based, or siloxan-based material. As the display device 100 is bent, the encapsulation layer ENCAP can be damaged, and the touch sensor metal located on the touch buffer layer T-BUF can be cracked or broken. Even when the display device 100 is bent, the touch buffer layer T-BUF including the organic insulating material and having the planarization performance can prevent the damage of the encapsulation layer ENCAP and/or the cracking or breaking of the metals (TSM, BRG) included in the touch sensor TS.

A protective layer PAC can be configured to cover the touch sensor TS. The protective layer PAC can be, for example, an organic insulating layer. Specifically, the protective layer PAC can be configured to cover the touch sensor TS and the touch interlayer insulating layer T-ILD.

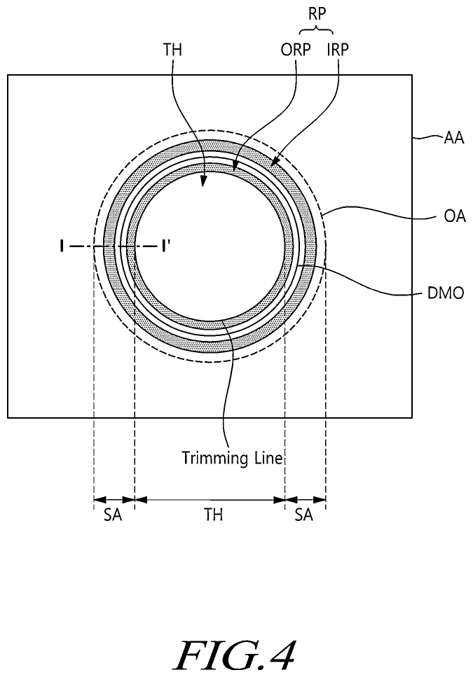

FIG. 4 is an enlarged plan view illustrating an example optical area structure of the display panel 110 in the display device 100 according to aspects of the present disclosure.

Referring to FIG. 4, an optical area OA can be disposed in the display area AA. A plurality of pixels can be disposed adjacent to the optical area OA. The optical area OA can be any one of the first optical area OA1 or the second optical area OA2 in FIGS. 1A to 1C described above.

In one or more example embodiments, the optical area OA can include a through hole TH and a surrounding area SA surrounding the through hole TH, and the display area AA can be located outside of the surrounding area SA. One or more rough patterns RP can be disposed in the surrounding area SA. For example, subpixels for displaying images may not be located in the optical area OA.

In one or more aspects, an optical electronic device located under the display panel can be configured to partially overlap with the through hole TH. This optical electronic device can be the first optical electronic device 11 described above.

The through hole TH can be formed as a corresponding portion of the substrate is cut along a trimming line and removed. The shape of the through hole TH can be circular as shown in FIG. 4, but can have various shapes such as oval, square, hexagon, or octagon, without being limited thereto.

The rough pattern RP can include an inner rough pattern IRP and an outer rough pattern ORP.

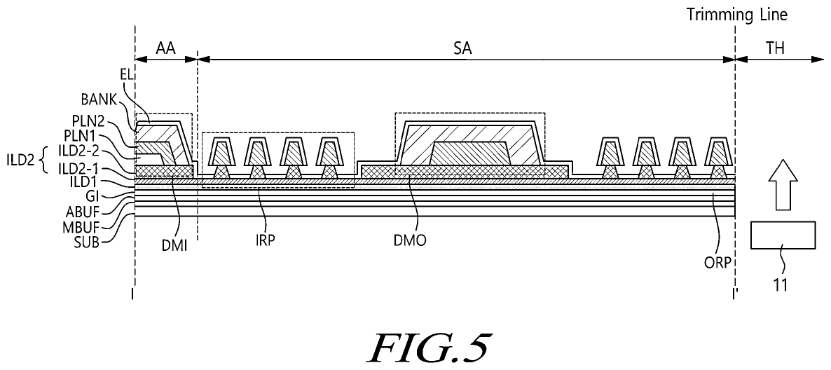

An outer dam DMO can be located in the surrounding area SA. For example, the outer dam DMO can be located between the inner rough pattern IRP and the outer rough pattern ORP such that the outer dam DMO separates the two patterns (IRP and ORP) from each other. The structure of the outer dam DMO will be described in detail in FIG. 5.

In one or more aspects, an inner dam can be further located in the display area AA. For example, the inner dam can be located outside of the inner rough pattern IRP. The inner dam can be configured to prevent an encapsulation layer (e.g., the second encapsulation layer PCL of FIG. 3) from overflowing toward outside of the display area AA. The structure of the inner dam will be described in detail in FIG. 5.

The shape of each dam can correspond to the shape of the through hole TH, and have a closed curve shape surrounding the through hole TH. For example, each dam and the through hole TH can have different closed curve shapes, or have closed curve shapes with a same shape and different sizes. For example, each dam and the through hole TH can have the same shape such as circle shapes with a common center and be arranged to be spaced apart from each other at a predefined interval. Each dam structure can have a stack of three layers disposed on the substrate SUB, without being limited thereto.

The shape of the rough pattern RP can correspond to the shape of the through hole TH, and have a closed curve shape surrounding the through hole TH. For example, the rough pattern RP and the through hole TH can have different closed curve shapes, or have closed curve shapes with a same shape and different sizes. For example, as shown in FIG. 4, the rough pattern RP and the through hole TH can have the same shape such as circle shapes with a common center and be arranged to be spaced apart from each other at a predefined interval.

A plurality of subpixels can be disposed in the display area AA, and each subpixel can include a light emitting element. In an example where light emitting elements are organic light emitting elements such as organic light emitting diodes, emission layers can be located in the display area AA, and the emission layers can be organic emission layers containing an organic material, without being limited thereto.

These organic emission layers can be configured to extend to at least a portion of the optical area OA.

Moisture can penetrate into the organic emission layers, and in this situation, there can occur defects such as darkening of subpixels. Moisture can penetrate into the area where the through hole TH is located.

An inorganic encapsulation layer (e.g., the inorganic encapsulation layer PAS1 described above) can be located on the rough pattern RP. Moisture can penetrate through the inorganic encapsulation layer, and in this situation, the rough pattern RP can act to lengthen a path through which moisture penetrates in the inorganic encapsulation layer. According to this implementation, the rough pattern RP can prevent moisture flowing in through the through hole TH, and the like from reaching an emission layer located in the display area AA.

FIG. 5 is a cross-sectional view taken along line I-I′ in the optical area OA of FIG. 4.

Referring to FIGS. 4 and 5, the optical area OA can include the through hole TH and the surrounding area SA surrounding the through hole TH, and the display area AA can be located outside of the surrounding area SA.

In one or more aspects, an optical electronic device located under the display panel can be configured to partially overlap with the through hole TH. This optical electronic device can be the first optical electronic device 11 described above.

Referring to FIG. 5, in one or more aspects, the display device 100 can include dam structures such as the inner dam DMI located in the display area AA, the outer dam DMO located in the surrounding area SA, and the like. For example, the outer dam DMO can be located between the inner rough pattern IRP and the outer rough pattern ORP such that the outer dam DMO separates the two patterns (IRP and ORP) from each other. Each dam structure can have a stack of three layers disposed on the substrate SUB, without being limited thereto. For example, at least one of the dam structures can include a first layer formed of a portion of a planarization layer, a second layer formed of a portion of a bank BANK, and a third layer formed of a portion of a spacer. The inner dam DMI can be configured to prevent an encapsulation layer (e.g., the second encapsulation layer PCL of FIG. 3) from overflowing toward outside of the display area AA.

As such a planarization layer, FIG. 5 illustrates the first and second planarization layers (PLN1 and PLN2). In the inner dam DMI, at least a portion of an emission layer EL can be located on the portion of the spacer.

In one or more aspects, one or more elements included in a light emitting element can be stacked on the outer dam DMO. For example, the emission layer EL and a common electrode can be stacked on the outer dam DMO such that the emission layer EL and the common electrode extend along or over the outer dam DMO.

In one or more aspects, a rough pattern can be formed inside and outside of the outer dam DMO. The rough pattern can include an inner rough pattern IRP and an outer rough pattern ORP. For example, the rough pattern can include one or more ridges and one or more valleys, which are formed in at least one surface of at least one insulating layer (e.g., ILD1, ILD2-1, ILD2-2, and/or the like).

The emission layer EL can be located in at least a portion of the rough pattern. The emission layer EL can be an organic emission layer EL containing an organic material, without being limited thereto. The emission layer EL can extend from the display area AA to at least a portion of the surrounding area SA.

In one or more aspects, the emission layer EL can be discontinuously disposed over the inner rough pattern IRP and the outer rough pattern ORP. According to these implementations, even if moisture flowing in through the through hole TH permeates into the emission layer EL located in the surrounding area SA, the moisture can be prevented from penetrating into the emission layer EL located in the display area AA. As the emission layer EL is discontinuously disposed in the rough patterns, the display device 100 or the display panel 110 can provide an advantage of lengthening a path through which moisture penetrates, and preventing the moisture flowing into the emission layer from reaching the display area AA.

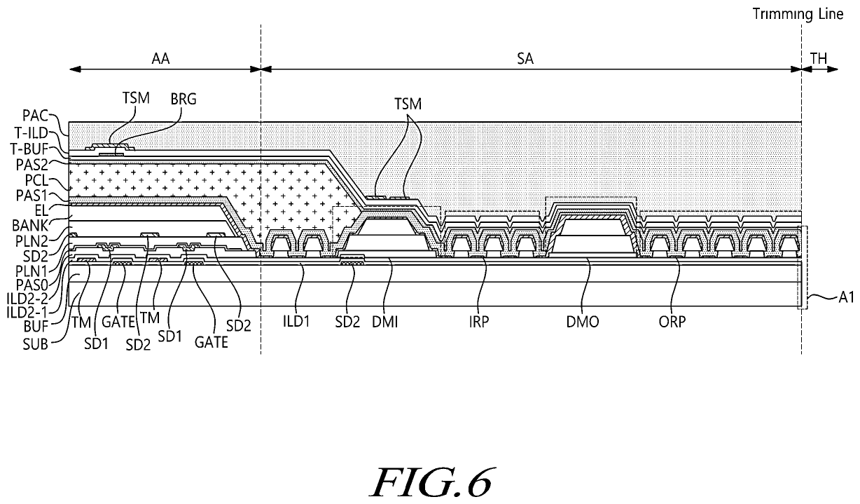

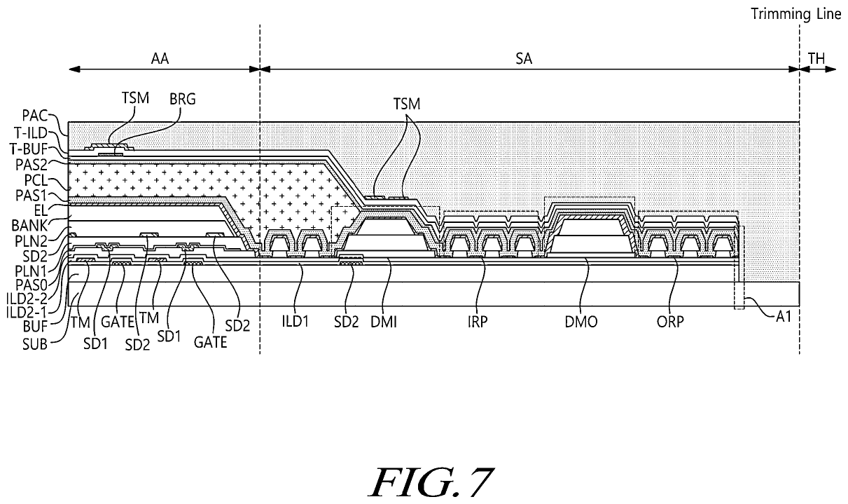

FIGS. 6 and 7 are cross-sectional views taken along line I-I′ in the optical area OA of FIG. 4.

Hereinafter, among configurations of the display panel 110 shown in FIG. 7, discussions on the same or substantially the same configurations as the configurations of the display panel 110 shown in FIG. 3 can be omitted for simplicity.

Referring to FIGS. 6 and 7, a substrate SUB can be disposed at the bottom of the display panel 110. The substrate SUB can include a first substrate SUB1, an interlayer insulating layer IPD, and a second substrate SUB2. The interlayer insulating layer IPD can be interposed between the first substrate SUB1 and the second substrate SUB2.

A buffer layer BUF can be disposed on the substrate SUB. The buffer layer BUF can include a multi-buffer layer MBUF, a first active buffer layer ABUF1, a second active buffer layer ABUF2, and a gate insulating layer GI.

A gate electrode GATE of the driving transistor DRT can be patterned and disposed on the buffer layer BUF.

A first interlayer insulating layer ILD1 can be configured to cover the buffer layer BUF and the gate electrode GATE.

A metal pattern TM can be patterned and disposed on the first interlayer insulating layer ILD1. The metal pattern TM can be located at a location different from the location where the driving transistor DRT is formed.

A second-first interlayer insulating layer ILD2-1 can be configured to cover the metal pattern TM. Specifically, the second-first interlayer insulating layer ILD2-1 can be configured to cover the first interlayer insulating layer ILD1 and the metal pattern TM.

A second-second interlayer insulating layer ILD2-2 can be disposed on the second-first interlayer insulating layer ILD2-1. After the second-second interlayer insulating layer ILD2-2 is disposed on the second-first interlayer insulating layer ILD2-1, a portion of the second-second interlayer insulating layer ILD2-2 can be removed by etching. The second-second interlayer insulating layer ILD2-2, the portion of which has been removed by the etching, can be divided into multiple portions, and some of the divided multiple portions can be included in the rough pattern and the one or more dams.

A first source-drain electrode pattern SD1 can be patterned and disposed on the second interlayer insulating layer ILD2. For example, the first source-drain electrode pattern SD1 can be patterned and disposed on the second-second interlayer insulating layer ILD2-2.

A passivation layer PAS0 can be disposed on the second-second interlayer insulating layer ILD2-2. Specifically, the passivation layer PAS0 can be configured to cover the two first source-drain electrode patterns SD1 and the second-second interlayer insulating layer ILD2-2. The passivation layer PAS0 can be disposed in the display area AA and be configured to cover the first source-drain electrode pattern SD1.

A first planarization layer PLN1 can be disposed on the passivation layer PAS0.

A second source-drain electrode pattern SD2 can be patterned and disposed on the first planarization layer PLN1.

After the second source-drain electrode pattern SD2 is disposed, a second planarization layer PLN2 can be deposited on the first planarization layer PLN1 and the second source-drain electrode pattern SD2. Thereafter, a portion of the second planarization layer PLN2 can be removed by etching. The second planarization layer PLN2, the portion of which has been removed by the etching, can be divided into multiple portions, and some of the divided multiple portions can be included in the rough pattern and the one or more dams.

A bank BANK can be disposed on the second planarization layer PLN2. Thereafter, a portion of the bank BANK can be removed by etching. The bank BANK, the portion of which has been removed by the etching, can be divided into multiple portions, and some of the divided multiple portions can be included in the rough pattern and the one or more dams. A spacer can be disposed on the bank BANK. Thereafter, a portion of the spacer can be removed by etching. The spacer, the portion of which has been removed by the etching, can be divided into multiple portions, and some of the divided multiple portions can be included in the rough pattern and the one or more dams.

An emission layer EL can be disposed on the bank BANK. All or at least a portion of the emission layer EL can be located between adjacent banks. As the emission layer EL is deposited on the entire surface, as well as the bank BANK, within a predefined area, a portion of the emission layer EL can be disposed on the top surface of the rough pattern and the top surface of the one or more dams.

A first encapsulation layer PAS1 can be configured to cover the emission layer EL, the rough pattern, the one or more dams, and the like. The first encapsulation layer PAS1 can include an inorganic insulating material, which can be deposited at a low temperature.

A second encapsulation layer PCL can be disposed on the first encapsulation layer PAS1. Specifically, the second encapsulation layer PCL can be disposed on a portion of the first encapsulation layer PAS1.

A third encapsulation layer PAS2 can be disposed on the second encapsulation layer PCL.

A touch buffer layer T-BUF can be disposed on the encapsulation layer ENCAP. Specifically, the touch buffer layer T-BUF can be disposed on the third encapsulation layer PAS2.

A bridge metal BRG can be patterned and disposed on the touch buffer layer T-BUF.

A touch interlayer insulating layer T-ILD can be configured to cover the touch buffer layer T-BUF and the bridge metal BRG. Touch sensor metals TSM can be disposed on the touch interlayer insulating layer T-ILD. One or more portions of the touch interlayer insulating layer T-ILD can be etched, and thereby, the touch interlayer insulating layer T-ILD can include a plurality of contact holes.

The touch sensor metals TSM can be electrically connected to the bridge metal BRG through contact holes of the touch interlayer insulating layer T-ILD.

A protective layer PAC can be configured to cover the touch interlayer insulating layer T-ILD and the touch sensor metals TSM. The protective layer PAC can be, for example, an organic insulating layer.

Referring to FIG. 6, the outer rough pattern ORP can be disposed in the surrounding area SA adjacent to the through hole TH. The outer dam DMO can be disposed outside of the outer rough pattern ORP. The inner rough pattern IRP can be disposed outside of the outer dam DMO. The inner dam DMI can be disposed outside of the inner rough pattern IRP. A portion of the entire rough pattern including the inner rough pattern IRP and the outer rough pattern ORP can be disposed outside of the inner dam DMI.

A trimming line can run along, or contact, the outer rough pattern ORP. A side surface of the outer rough pattern ORP can correspond to a boundary, or a boundary area, of the through hole TH. For example, the boundary or the boundary area of the through hole TH can correspond to a side surface of the protective layer PAC, a side surface of the outer rough pattern ORP, a side surface of the buffer layer BUF, and a side surface of the substrate SUB.

In contrast, referring to FIG. 7, unlike FIG. 6, a boundary, or a boundary area, of the through hole TH in FIG. 7 can correspond to a side surface of the protective layer PAC and a side surface of the substrate SUB. Elements (i.e., stacked elements) on the substrate SUB except for the protective layer PAC can be disposed to be spaced apart from the trimming line. This implementation can prevent elements (i.e., stacked elements) such as the outer rough pattern ORP, and the like from being damaged during the process of forming the through hole TH. The trimming line can be referred to as a trimming area.

In one or more aspects, the first encapsulation layer PAS1 can include a plurality of insulating layers. For example, the first encapsulation layer PAS1 can be disposed in the combined form of silicon nitride (SiNx), silicon oxide (SiOx), and silicon oxynitride (SiON). As one example, the first encapsulation layer PAS1 can include three insulating layers, without being limited thereto. For example, the bottom layer of the first encapsulation layer PAS1 can include silicon nitride (SiNx). The middle layer of the first encapsulation layer PAS1 can include silicon oxynitride (SiON). The top layer of the first encapsulation layer PAS1 can include silicon oxide (SiOx).

In the example where the top layer of the first encapsulation layer PAS1 includes silicon oxide (SiOx), the second encapsulation layer PCL can be disposed while spreading more easily on the first encapsulation layer PAS1. However, when the top layer of the first encapsulation layer PAS1 includes silicon oxide (SiOx), oxygen can penetrate through the top layer of the first encapsulation layer PAS1, which includes silicon oxide (SiOx).

To address this issue, one or more aspects of the present disclosure can provide the display device 100 capable of preventing oxygen from penetrating into an encapsulation layer.

One or more aspects of the present disclosure can provide the display device 100 including an encapsulation layer capable of preventing penetration of moisture during the process of forming a through hole.

One or more aspects of the present disclosure can provide the display device 100 including a second encapsulation layer that is located on a first encapsulation layer, which is an inorganic layer, has high spreadability, and is capable of preventing oxygen from penetrating into the first encapsulation layer.

One or more aspects of the present disclosure can provide the display device 100 capable of preventing oxygen from penetrating into an encapsulation layer and thereby being driven at low power.

One or more example embodiments of the present disclosure are discussed in detail below.

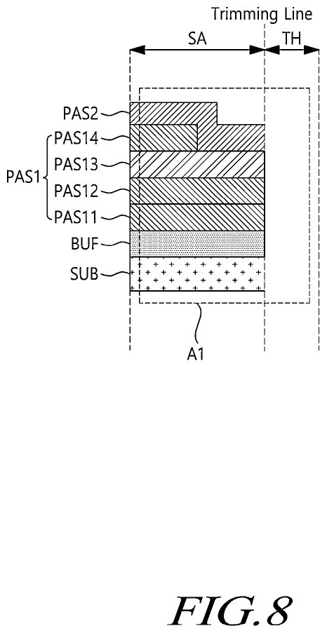

FIGS. 8 to 11 are cross-sectional views illustrating a boundary area between the contact hole TH and the surrounding area in FIG. 4. FIGS. 6 and 8 illustrate a first enlarged area A1 of the display panel 110.

Referring to FIGS. 8 to 11, the substrate SUB can be disposed at the bottom of the display panel 110. The substrate SUB can include the through hole TH and the surrounding area SA. The substrate SUB can include glass, plastic, or a flexible polymer film. For example, the flexible polymer film can be made of any one of polyethylene terephthalate (PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene (PS), which is only an example and is not necessarily limited thereto.

The buffer layer BUF can be disposed on the substrate SUB.

The first encapsulation layer PAS1 can be disposed on the buffer layer BUF. The first encapsulation layer PAS1 can have a stepped end, without being limited thereto.

The first encapsulation layer PAS1 can include a plurality of insulating layers. The plurality of insulating layers can be three layers or four layers, without being limited thereto, more or less layers are also possible. For example, the first encapsulation layer PAS1 can include two layers.

Referring to FIG. 8, in the example when the first encapsulation layer PAS1 is configured with a stack of four layers, the first encapsulation layer PAS1 can include a first insulating layer PAS11 including silicon nitride (SiNx), a second insulating layer PAS12 including silicon oxynitride (SiON), which is disposed on the first insulating layer PAS11, a third insulating layer PAS13 including silicon oxynitride (SiON), which is disposed on the second insulating layer PAS12, and a fourth insulating layer PAS14 including silicon oxide (SiOx), which is disposed on a portion of the third insulating layer PAS13, without being limited thereto. Alternatively, in the example when the first encapsulation layer PAS1 is configured with a stack of two layers, the first encapsulation layer PAS1 can include the third insulating layer PAS13 and the fourth insulating layer PAS14 disposed on a portion of the third insulating layer PAS13.

In the example when the first encapsulation layer PAS1 is configured with a stack of three layers, the first encapsulation layer PAS1 can include a first insulating layer including silicon nitride (SiNx), a second insulating layer including silicon oxynitride (SiON), and a third insulating layer including silicon oxide (SiOx), without being limited thereto.

Thus, in the example of FIG. 8, the bottom layer PAS11 of the first encapsulation layer PAS1 can include silicon nitride (SiNx), and the top layer PAS14 of the first encapsulation layer PAS1 can include silicon oxide (SiOx). Hereinafter, for convenience of explanation, discussions are provided based on examples where the first encapsulation layer PAS1 is configured with the stack of four layers.

The bottom layer PAS11 can have a width (i.e., a distance between both opposing ends) greater than the top layer PAS14. For example, the bottom layer PAS11 can extend rightwardly beyond the right edge of the top layer PAS14. Similarly, the second insulating layer PAS12 and the third insulating layer PAS13 can have a width (i.e., a distance between both opposing ends) greater than the top layer PAS14, without being limited thereto. For example, the second insulating layer PAS12 and the third insulating layer PAS13 can extend rightwardly beyond the right edge of the top layer PAS14, without being limited thereto.

The fourth insulating layer PAS14 can be disposed on a portion of the third insulating layer PAS13.

A portion of the first encapsulation layer PAS1 can be disposed adjacent to the through hole TH. Each of the first insulating layer PAS11, the second insulating layer PAS12, and the third insulating layer PAS13 can be disposed adjacent to the through hole TH.

The fourth insulating layer PAS14 can be disposed to be spaced apart from the through hole TH. In one or more aspects, the fourth insulating layer PAS14 can be disposed on the entire top surface of the third insulating layer PAS13 within a predefined area, and the fourth insulating layer PAS14 may not be disposed on a portion of the third insulating layer PAS13 adjacent to the through hole TH. In one or more aspects, the third encapsulation layer PAS2 can be disposed on the first encapsulation layer PAS1. For example, the third encapsulation layer PAS2 can be disposed on the portion of the third insulating layer PAS13 adjacent to the through hole TH and the fourth insulating layer PAS14.

The third encapsulation layer PAS2 can be configured to cover the first encapsulation layer PAS1.

The third encapsulation layer PAS2 can be configured to cover a side surface (e.g., a right side surface) of the fourth insulating layer PAS14 and a portion of the third insulating layer PAS13.

The third encapsulation layer PAS2 can be disposed in a stepped pattern.

A portion of the third encapsulation layer PAS2 disposed on the right side of the surrounding area SA can be disposed in parallel with the fourth insulating layer PAS14 in the horizontal direction, and be configured to overlap with the third insulating layer PAS13 in the vertical direction. A portion of the third encapsulation layer PAS2 disposed on the left side of the surrounding area SA can be configured to overlap with the third insulating layer PAS13 in the vertical direction. The portion of the third encapsulation layer PAS2 disposed on the left side of the surrounding area SA can be disposed higher than the portion of the third encapsulation layer PAS2 disposed on the right side of the surrounding area SA, without being limited thereto.

The third encapsulation layer PAS2 can be disposed on the first encapsulation layer PAS1 and disposed adjacent to the through hole TH.

Respective one side surface (e.g., a respective right side surface) of each of the first insulating layer PAS11, the second insulating layer PAS12, the third insulating layer PAS13, and the third encapsulation layer PAS2 can correspond to a trimming line or trimming area.

Each of the first insulating layer PAS11, the second insulating layer PAS12, the third insulating layer PAS13, and the third encapsulation layer PAS2 can have a cut shape at the trimming area.

Even when each of the first insulating layer PAS11, the second insulating layer PAS12, the third insulating layer PAS13, and the third encapsulation layer PAS2 are cut along the trimming line, since the third encapsulating layer PAS2 is configured to cover the side surface of the fourth insulating layer PAS14, the fourth insulating layer PAS14 can be therefore protected from the penetration of moisture.

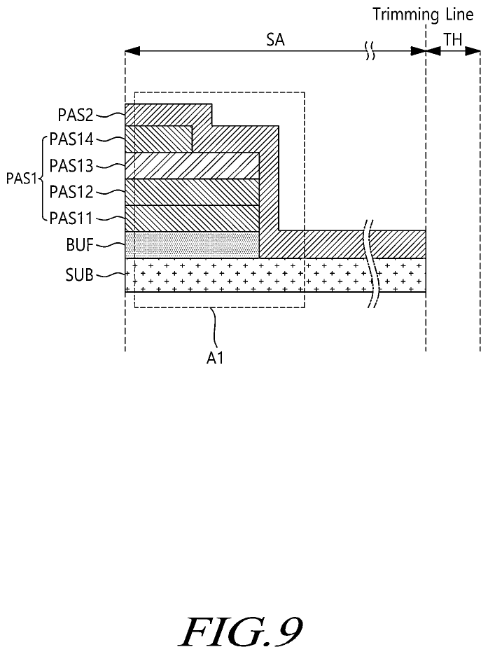

Referring to FIGS. 7 and 9, a boundary of the through hole TH in FIG. 7 can correspond to a side surface of the protective layer PAC and a side surface of the substrate SUB. The first encapsulation layer PAS1 can be disposed to be spaced apart from the through hole TH. For example, each of the first insulating layer PAS11, the second insulating layer PAS12, the third insulating layer PAS13 and the fourth insulating layer PAS14 can be disposed to be spaced apart from the through hole TH. The third encapsulation layer PAS2 can be disposed adjacent to the through hole TH. The first encapsulation layer PAS1 and third encapsulation layer PAS2 can be disposed in a stepped pattern.

Referring to FIGS. 8 and 9, unlike the third encapsulation layer PAS2 of FIG. 8, the third encapsulation layer PAS2 of FIG. 9 can be configured to cover all of a side surface (e.g., a right side surface) of the first encapsulation layer PAS1.

The third encapsulation layer PAS2 can include a portion disposed along the side surface of the first encapsulation layer PAS1.

The third encapsulation layer PAS2 can be configured to cover a respective side surface (e.g., a respective right side surface) of each of a first insulating layer PAS11, a second insulating layer PAS12, a third insulating layer PAS13 and a fourth insulating layer PAS14, and a portion of the top surface of the substrate SUB. Therefore, a portion of the third encapsulation layer PAS2 contacting the substrate SUB can be disposed adjacent to the through hole TH. Further, the third encapsulation layer PAS2 can be configured to cover a portion of the top surface of the third insulating layer PAS13 and the top surface of the fourth insulating layer PAS14. Further, the third encapsulation layer PAS2 can be configured to cover respective side surfaces (e.g., respective right side surfaces) of the buffer layer BUF.

The third encapsulation layer PAS2 and the substrate SUB can have cut shapes at the trimming area. Respective side surfaces of the third encapsulation layer PAS2 and the substrate SUB can correspond to the trimming area.

Even when each of the third encapsulation layer PAS2 and the substrate SUB is cut along the trimming line, since the third encapsulation layer PAS2 is configured to cover the side surface of the first encapsulation layer PAS1, a fourth insulating layer PAS14 can be therefore protected from the penetration of moisture.

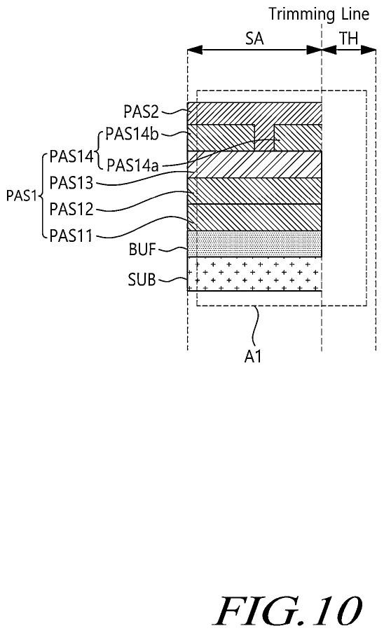

Referring to FIGS. 8 and 10, unlike the fourth insulating layer PAS14 of FIG. 8, a fourth insulating layer PAS14 of FIG. 10 can be configured to expose a portion of a third insulating layer PAS13, and the fourth insulating layer PAS14 can include a portion adjacent to the through hole TH.

After the fourth insulating layer PAS14 is deposited on the entire top surface of the third insulating layer PAS13 within a predefined area, a portion of the fourth insulating layer PAS14 spaced apart from the through hole TH can be removed by etching.

Through this process, the fourth insulating layer PAS14 can include a first part PAS14a adjacent to the through hole TH, and a second part PAS14b spaced apart from the through hole TH.

The third encapsulation layer PAS2 can be configured to contact a portion of the third insulating layer PAS13 between the first part PAS14a and the second part PAS14b of the fourth insulating layer PAS14. Referring to FIG. 10, the third encapsulation layer PAS2 can have a “T” shape. For example, the third encapsulation layer PAS2 can configure to cover the first part PAS14a, the second part PAS14b and the exposed portion of the third insulating layer PAS13.

The first part PAS14a can be spaced apart from the second part PAS14b. In addition, the first part PAS14a may not be fully separated from the second part PAS14b, and an area between the first part PAS14a and the second part PAS14b can be an area where a through hole is formed.

The first part PAS14a can be disposed adjacent to the through hole TH and configured to overlap with the third insulating layer PAS13 in the vertical direction.

The second part PAS14b can be disposed to be spaced apart from the through hole TH and configured to overlap with the third insulating layer PAS13 in the vertical direction.

A portion of the third encapsulation layer PAS2 can be disposed in the area between the first part PAS14a and the second part PAS14b, and the third encapsulation layer PAS2 can be disposed in parallel with the first part PAS14a and the second part PAS14b in the horizontal direction. Specifically, the portion of the third encapsulation layer PAS2 disposed in the area between the first part PAS14a and the second part PAS14b can be disposed in parallel with the first part PAS14a and the second part PAS14b in the horizontal direction.

A respective side surface (e.g., a respective right side surface) of each of the first encapsulation layer PAS1 and the third encapsulation layer PAS2 can correspond to the trimming area. The first encapsulation layer PAS1 and the third encapsulation layer PAS2 can have cut shapes at the trimming area.

Referring to FIG. 10, as the second part PAS14b of the fourth insulating layer PAS14 is disposed to be spaced apart from the through hole TH, the fourth insulating layer PAS14 can be protected from the penetration of moisture, and as the first part PAS14a of the fourth insulating layer PAS14 is disposed adjacent to the through hole TH, the first encapsulation layer PAS1 can have a structurally strong end.

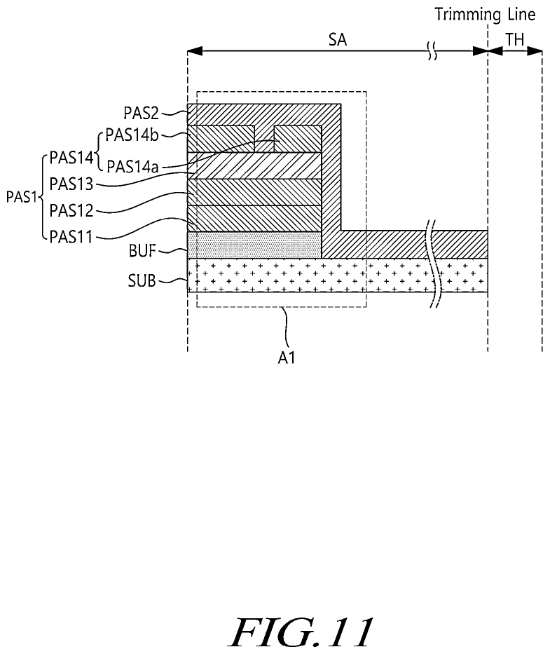

Referring to FIGS. 7 and 11, a boundary of the through hole TH in FIG. 7 can correspond to a side surface of the protective layer PAC and a side surface of the substrate SUB. The first encapsulation layer PAS1 can be configured to be spaced apart from the through hole TH.

Referring to FIGS. 10 and 11, unlike the third encapsulation layer PAS2 of FIG. 10, the third encapsulation layer PAS2 of FIG. 11 can be configured to cover all of a side surface (e.g., a right side surface) of the first encapsulation layer PAS1.

The third encapsulation layer PAS2 can be configured to cover the side surface of the first encapsulation layer PAS1 and a portion of the top surface of the substrate SUB. Specifically, the third encapsulation layer PAS2 can be configured to cover a respective side surface (e.g., a respective right side surface) of each of a first insulating layer PAS11, a second insulating layer PAS12, a third insulating layer PAS13 and the fourth insulating layer PAS14, and a portion of the top surface of the substrate SUB. Therefore, a portion of the third encapsulation layer PAS2 contacting the substrate SUB can be disposed adjacent to the through hole TH.

The third encapsulation layer PAS2 can be configured to cover a side surface of the first part PAS14a of the fourth insulating layer PAS14. The third encapsulation layer PAS2 can be configured to cover respective side surfaces (e.g., respective right side surfaces) of the first insulating layer PAS11, the second insulating layer PAS12, and the third insulating layer PAS13. Further, the third encapsulation layer PAS2 can be configured to cover respective side surfaces (e.g., respective right side surfaces) of the buffer layer BUF.

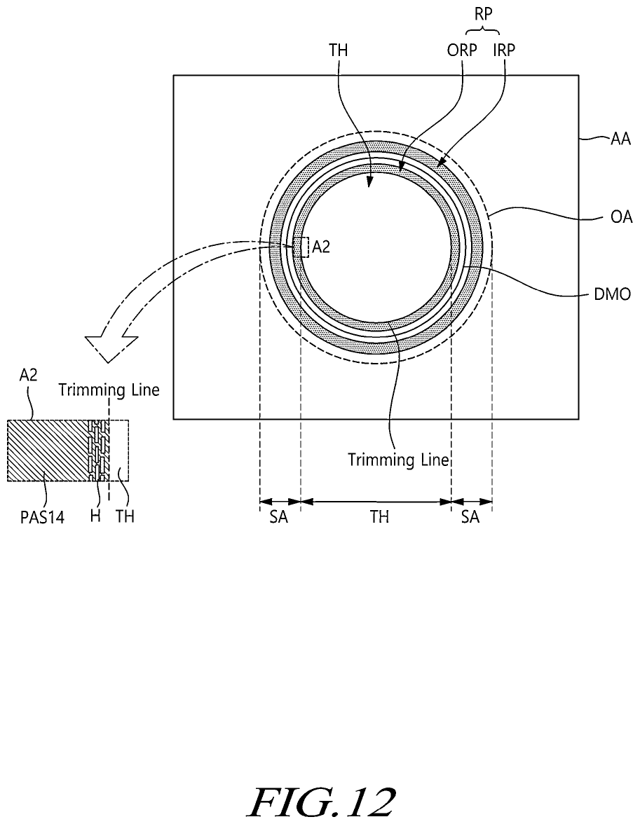

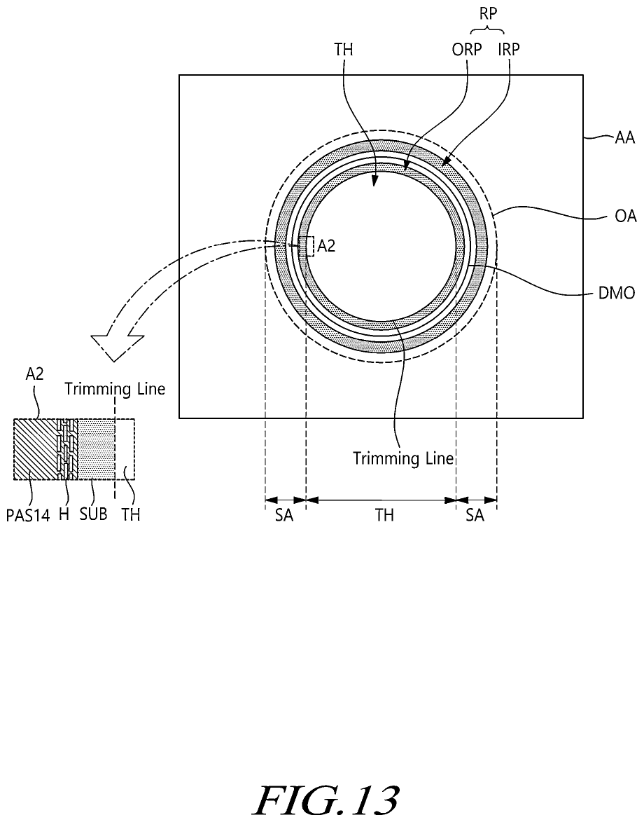

FIGS. 12 and 13 are plan views illustrating a boundary area between the contact hole (or through hole) TH and the surrounding area SA in FIG. 4. Particularly, FIGS. 12 and 13 illustrate a second enlarged area A2 of the display panel 110.

Referring to FIGS. 12 and 13, the fourth insulating layer PAS14 can include a groove area where a plurality of grooves H are disposed.

A distance between the fourth insulating layer PAS14 and the through hole TH shown in FIG. 12 can be the same, or substantially the same, as a distance between the fourth insulating layer PAS14 and the through hole TH shown in FIG. 6. Referring to FIG. 12, a side surface of the fourth insulating layer PAS14 can correspond to the trimming line. Specifically, the side surface of the groove area of the fourth insulating layer PAS14 can be disposed adjacent to the trimming line. The groove area of the fourth insulating layer PAS14 can be disposed adjacent to the trimming line.

A distance between the fourth insulating layer PAS14 and the through hole TH shown in FIG. 13 can be the same, or substantially the same, as a distance between the fourth insulating layer PAS14 and the through hole TH shown in FIG. 7. Referring to FIG. 13, a side surface of the fourth insulating layer PAS14 can be disposed to be spaced apart from the through hole TH. The groove area of the fourth insulating layer PAS14 can be disposed to be spaced apart from the through hole TH.

As the fourth insulating layer PAS14 includes a plurality of grooves H, a moisture penetration distance through the fourth insulating layer PAS14 can be increased.

The plurality of grooves H can be designed in various shapes to increase the moisture penetration distance. For example, the plurality of grooves H can be arranged so that moisture penetrating the fourth insulating layer PAS14 can move in a zigzag pattern.

The example embodiments described above will be briefly described as follows.

According to the example embodiments described herein, a display device can be provided that includes a substrate including a through hole and a surrounding area surrounding the through hole, a first passivation layer disposed on the substrate and including a first insulating layer and a second insulating layer disposed on a portion of the first insulating layer, and a second passivation layer configured to cover the first passivation layer.

In one or more aspects, the substrate can comprise a first substrate, and a second substrate with an interlayer insulating layer interposed therebetween.

In one or more aspects, the second passivation layer can be configured to cover a side surface of the second insulating layer and a portion of a top surface of the first insulating layer.

In one or more aspects, the second passivation layer can be disposed in a stepped pattern.

In one or more aspects, the first passivation layer can be disposed in a stepped pattern.

In one or more aspects, the first passivation layer can be disposed adjacent to the through hole, and the second passivation layer can be disposed on the first passivation layer and disposed adjacent to the through hole.

In one or more aspects, the first insulating layer can be disposed adjacent to the through hole, and the second insulating layer can be disposed to be spaced apart from the through hole.

In one or more aspects, the substrate can further include a trimming area that is a boundary area between the through hole and the surrounding area, and a side surface of the first insulating layer of the first passivation layer and a side surface of the second passivation layer can correspond to the trimming area.

In one or more aspects, the second passivation layer can be configured to cover a side surface of the first insulating layer.

In one or more aspects, the second passivation layer can be configured to cover the side surface of the first insulating layer and a portion of a top surface of the substrate.

In one or more aspects, the first passivation layer can be disposed to be spaced apart from the through hole, and the second passivation layer can be disposed adjacent to the through hole.

In one or more aspects, the substrate further can include a trimming area that is a boundary area between the through hole and the surrounding area, and a side surface of the second passivation layer and a side surface of the substrate can correspond to the trimming area.

In one or more aspects, the second insulating layer can include a first part adjacent to the through hole, and a second part spaced apart from the through hole.

In one or more aspects, the second passivation layer can be configured to contact the first insulating layer between the first part of the second insulating layer and the second part of the second insulating layer.

In one or more aspects, the second passivation layer can be configured to cover a side surface of the first insulating layer and a side surface of the first part of the second insulating layer.

In one or more aspects, the second passivation layer can be configured to cover the side surface of the first insulating layer and a portion of a top surface of the substrate.

In one or more aspects, the first passivation layer can be disposed to be spaced apart from the through hole, and the second passivation layer can be disposed adjacent to the through hole.

In one or more aspects, the second insulating layer can include a groove area where a plurality of grooves are disposed.

In one or more aspects, the groove area can be disposed adjacent to the through hole.

In one or more aspects, the groove area can be disposed to be spaced apart from the through hole.

In one or more aspects, the display device can further include an optical electronic device configured to overlap with the through hole.

In one or more aspects, the through hole can be an area where an image is not displayed.

In one or more aspects, the substrate can further include a display area surrounding the surrounding area, and the second passivation layer can be disposed on the display area and the surrounding area.

A display device according to one or more exemplary embodiments of the present disclosure can be applied to mobile apparatuses, video phones, smart watches, watch phones, wearable apparatuses, foldable apparatuses, rollable apparatuses, bendable apparatuses, flexible apparatuses, curved apparatuses, variable apparatuses, sliding apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, home appliances, etc., but embodiments of the present disclosure are not limited thereto.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein can be applied to other embodiments and applications without departing from the scope of the present disclosure. The above description and the accompanying drawings provide examples of the technical features of the present disclosure for illustrative purposes only. For example, the disclosed embodiments are intended to illustrate the scope of the technical features of the present disclosure.

What is claimed is:

1. A display device comprising:
a substrate comprising a through hole and a surrounding area surrounding the through hole;
a first passivation layer disposed on the substrate and comprising a first insulating layer and a second insulating layer disposed on a portion of the first insulating layer; and
a second passivation layer configured to cover the first passivation layer.

2. The display device of claim 1, wherein the substrate comprises:
a first substrate;
a second substrate; and
an interlayer insulating layer interposed between the first and second substrates.

3. The display device of claim 1, wherein the second passivation layer is configured to cover a side surface of the second insulating layer and a portion of a top surface of the first insulating layer.

4. The display device of claim 3, wherein the second passivation layer is disposed in a stepped pattern.

5. The display device of claim 1, wherein the first passivation layer is disposed in a stepped pattern.

6. The display device of claim 1, wherein the first passivation layer is disposed adjacent to the through hole, and the second passivation layer is disposed on the first passivation layer and disposed adjacent to the through hole.

7. The display device of claim 1, wherein the first insulating layer is disposed adjacent to the through hole, and the second insulating layer is disposed to be spaced apart from the through hole.

8. The display device of claim 3, wherein the substrate further comprises a trimming area that is a boundary area between the through hole and the surrounding area, and
wherein a side surface of the first insulating layer of the first passivation layer and a side surface of the second passivation layer correspond to the trimming area.

9. The display device of claim 3, wherein the second passivation layer is configured to cover a side surface of the first insulating layer.

10. The display device of claim 9, wherein the second passivation layer is configured to cover the side surface of the first insulating layer and a portion of a top surface of the substrate.

11. The display device of claim 3, wherein the first passivation layer is disposed to be spaced apart from the through hole, and the second passivation layer is disposed adjacent to the through hole.

12. The display device of claim 9, wherein the substrate further comprises a trimming area that is a boundary area between the through hole and the surrounding area, and
wherein a side surface of the second passivation layer and a side surface of the substrate correspond to the trimming area.

13. The display device of claim 1, wherein the second insulating layer comprises:
a first part adjacent to the through hole; and
a second part spaced apart from the through hole.

14. The display device of claim 13, wherein the second passivation layer is configured to contact the first insulating layer between the first part of the second insulating layer and the second part of the second insulating layer.

15. The display device of claim 13, wherein the second passivation layer is configured to cover a side surface of the first insulating layer and a side surface of the first part of the second insulating layer.

16. The display device of claim 13, wherein the second passivation layer is configured to cover the side surface of the first insulating layer and a portion of a top surface of the substrate.

17. The display device of claim 3, wherein the first passivation layer is disposed to be spaced apart from the through hole, and the second passivation layer is disposed adjacent to the through hole.

18. The display device of claim 1, wherein the second insulating layer comprises a groove area where a plurality of grooves are disposed.

19. The display device of claim 18, wherein the groove area is disposed adjacent to the through hole.

20. The display device of claim 18, wherein the groove area is disposed to be spaced apart from the through hole.

21. The display device of claim 1, further comprising an optical electronic device configured to overlap with the through hole.

22. The display device of claim 1, wherein the through hole is an area where an image is not displayed.

23. The display device of claim 1, wherein the substrate further comprises a display area surrounding the surrounding area, and
wherein the second passivation layer is disposed on the display area and the surrounding area.
